(19) United States
(12) Patent Application Publication
(10) Pub. No.: US 2025/0081335 A1
(43) Pub. Date: Mar. 6, 2025

(54) ELECTRONIC DEVICE

(71) Applicant: Industrial Technology Research Institute, Hsinchu (TW)

(72) Inventors: Yi-Rong Lin, Hsinchu City (TW); Hsiao-Fen Wei, Hsinchu County (TW); Chung-Wei Wang, Hsinchu City (TW); Li-Wei Yao, Hsinchu County (TW)

(73) Assignee: Industrial Technology Research Institute, Hsinchu (TW)

(21) Appl. No.: 18/820,222

(22) Filed: Aug. 29, 2024

Related U.S. Application Data
(60) Provisional application No. 63/535,564, filed on Aug. 30, 2023.

(30) Foreign Application Priority Data
Jul. 29, 2024 (TW) 113128057

(51) Int. Cl. H05K 1/02

(52) U.S. Cl. CPC H05K 1/0296; H05K 1/0256; H05K 1/0271; H05K 1/0284; H05K 2201/09045; H05K 2201/09118; H05K 2201/09236

(57) ABSTRACT

An electronic device includes a surface structure. The surface structure has a curved surface and includes a substrate, a first conductive line, and a first dielectric pattern. The first conductive line is disposed above the substrate. The first dielectric pattern is disposed above the first conductive line and overlaps with the first conductive line. The surface structure has a first region and a second region. The first dielectric pattern in the first region has a first average width, the first dielectric pattern in the second region has a second average width, and the first average width is different from the second average width.

### CROSS-REFERENCE TO RELATED APPLICATION

This application claims the priority benefits of U.S. provisional application Ser. No. 63/535,564, filed on Aug. 30, 2023, and Taiwan application serial no. 113128057, filed on Jul. 29, 2024. The entirety of each of the above-mentioned patent applications is hereby incorporated by reference herein and made a part of this specification

### TECHNICAL FIELD

The disclosure relates to a device, and in particular to an electronic device.

### BACKGROUND

With the advancement of technology, an electronic circuit of an electronic device may be integrated with a molding body through mold electronics technology, so that the electronic circuit may be arbitrarily laid out along with the curved surface of the molding body. However, the electronic circuit may experience abnormalities such as circuit delamination or breakage due to impacts such as various deformation and stress. Moreover, in order to cope with diverse applications and requirements, the circuit design is becoming increasingly complex. For example, the design including a multi-layer circuit stack causes the circuit abnormalities to be more likely to occur, thereby affecting the reliability of the electronic device. Therefore, how to improve the reliability of mold electronics is currently an issue that needs to be solved.

### SUMMARY

An electronic device is introduced herein, which can reduce the risk of circuit abnormalities, thereby improving reliability.

An electronic device according to an embodiment of the disclosure includes a surface structure. The surface structure has a curved surface. The surface structure includes a substrate, a first conductive line, and a first dielectric pattern. The first conductive line is disposed above the substrate. The first dielectric pattern is disposed above the first conductive line and overlaps with the first conductive line. The surface structure has a first region and a second region. The first dielectric pattern in the first region has a first average width. The first dielectric pattern in the second region has a second average width. The first average width is different from the second average width.

An electronic device according to another embodiment of the disclosure includes a substrate, a first conductive line, a second conductive line, and a first dielectric pattern. The substrate has a curved surface. The first conductive line is disposed above the substrate. The first conductive line has a first thickness. The second conductive line is disposed above the first conductive line. The second conductive line has a second thickness. The first dielectric pattern is disposed between the first conductive line and the second conductive line. The first dielectric pattern has a third thickness. A ratio of the third thickness to the first thickness and a ratio of the third thickness to the second thickness are respectively between 0.5 and 10.

An electronic device according to yet another embodiment of the disclosure includes a surface structure. The surface structure includes a flexible substrate and a first conductive line. The first conductive line is disposed on the flexible substrate. The surface structure is stretched to form a curved surface. A routing direction of the first conductive line on a projection surface is different from a component force direction of a tensile force subjected to any point on the first conductive line parallel to the projection surface.

Based on the above, the electronic structure according to the embodiments of the disclosure includes the surface structure. The surface structure includes the conductive line and the dielectric pattern corresponding to the conductive line. Through the dielectric pattern having different widths according to the tensile rate subjected to the corresponding conductive line, through controlling the thickness ratio of the dielectric pattern to the corresponding conductive line, or through the routing direction of the conductive line being different from the tensile direction subjected thereto, the deformation stress subjected to the conductive line can be alleviated to reduce the risk of delamination or breakage of the conductive line, thereby improving the reliability of the electronic device.

Several exemplary embodiments accompanied with figures are described in detail below to further describe the disclosure in details.

### BRIEF DESCRIPTION OF THE DRAWINGS

The accompanying drawings are included to provide a further understanding, and are incorporated in and constitute a part of this specification. The drawings illustrate exemplary embodiments and, together with the description, serve to explain the principles of the disclosure.

FIG. 1A is a schematic three-dimensional view of an electronic device according to an embodiment of the disclosure.

FIG. 1B is a schematic top view of an electronic device according to an embodiment of the disclosure.

FIG. 1C is a schematic cross-sectional view of an electronic device according to an embodiment of the disclosure.

FIG. 2A is a schematic three-dimensional view of an electronic device according to an embodiment of the disclosure.

FIG. 2B is a schematic top view of an electronic device according to an embodiment of the disclosure.

FIG. 3A is a schematic three-dimensional view of an electronic device according to an embodiment of the disclosure.

FIG. 3B is a schematic top view of an electronic device according to an embodiment of the disclosure.

FIG. 4A is a schematic three-dimensional view of an electronic device according to an embodiment of the disclosure.

FIG. 4B is a schematic top view of an electronic device according to an embodiment of the disclosure.

FIG. 5A is a schematic three-dimensional view of an electronic device according to an embodiment of the disclosure.

FIG. 5B is a schematic top view of an electronic device according to an embodiment of the disclosure.

FIG. 5C is a schematic cross-sectional view of an electronic device according to an embodiment of the disclosure.

FIG. 6A, FIG. 6B, FIG. 7A, FIG. 7B, FIG. 8A, FIG. 8B, FIG. 9, and FIG. 10 are schematic views of a manufacturing process of an electronic device according to an embodiment of the disclosure.

### DETAILED DESCRIPTION OF DISCLOSURED EMBODIMENTS

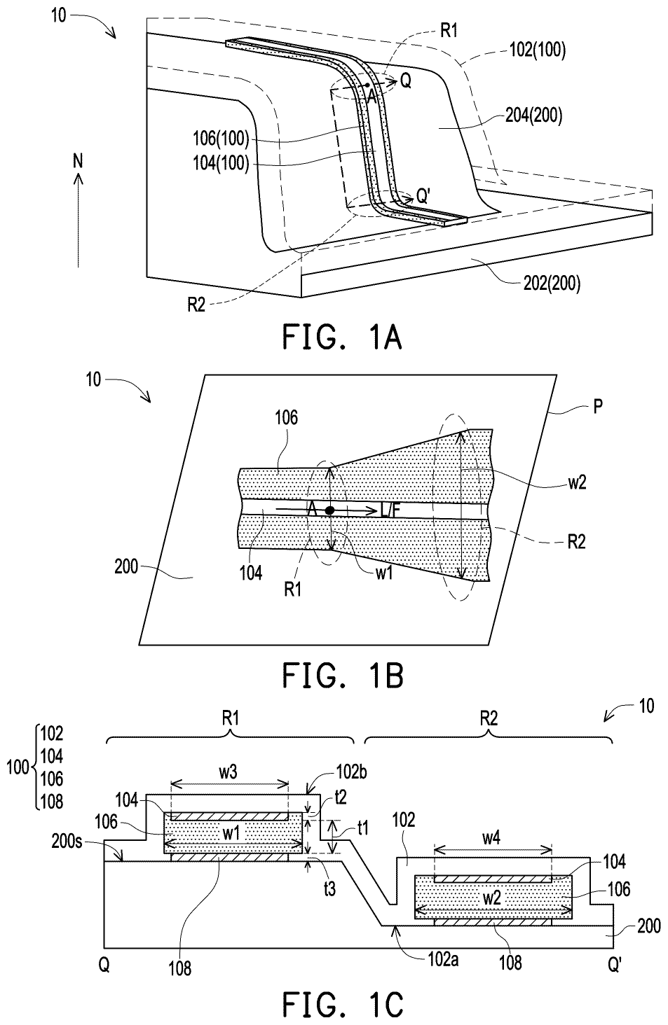

FIG. 1A is a schematic three-dimensional view of an electronic device 10 according to an embodiment of the disclosure. FIG. 1B is a schematic top view of the electronic device 10 according to an embodiment of the disclosure. FIG. 1C is a schematic cross-sectional view of the electronic device 10 according to an embodiment of the disclosure. FIG. 1B may be a partial schematic top view of FIG. 1A and may also be regarded as the orthographic projection of the electronic device 10 on a projection surface P. FIG. 1C may be a schematic cross-sectional view along a sectional line Q-Q′ of FIG. 1A. For clarity of illustration, a substrate 102 is omitted in FIG. 1B, and the omitted part may be understood with reference to FIG. 1A and FIG. 1C.

Please refer to FIG. 1A, FIG. 1B, and FIG. 1C. The electronic device 10 includes a surface structure 100. The surface structure 100 includes the substrate 102, a first conductive line 104, and a first dielectric pattern 106. The substrate 102 has a first surface 102a and a second surface 102b opposite to the first surface 102a. The first conductive line 104 is disposed on the first surface 102a of the substrate 102, and the first dielectric pattern 106 is disposed on the first conductive line 104 and overlaps with the first conductive line 104. The surface structure 100 has a curved surface and is stretched (for example, through a thermoplastic molding process) to form the curved surface with concavity, convexity, or other deformations. In other words, the surface structure 100 (such as including the substrate 102, the first conductive line 104, and the first dielectric pattern 106) is stretched and deformed due to the impact of morphological convexity or concavity.

In some embodiments, the first dielectric pattern 106 completely overlaps with and directly contacts the first conductive line 104. However, the disclosure is not limited thereto. In other embodiments, the first dielectric pattern 106 may partially overlap with the first conductive line 104.

In some embodiments, the width of the first dielectric pattern 106 is greater than the width of the first conductive line 104 to cover a sidewall of the first conductive line 104 and a surface opposite to the substrate 102. In some embodiments, the first dielectric pattern 106 may have a uniform width or a non-uniform width.

In some embodiments, the surface structure 100 may have a first region R1 and a second region R2. Tensile rates respectively subjected to conductive lines (for example, the first conductive line 104 or a second conductive line 108 described below) in the first region R1 and the second region R2 are greater than or equal to 5%. In the disclosure, the tensile rate refers to a rate of change of the length of the conductive line (for example, the first conductive line 104 or the second conductive line 108 described below) of the region before and after thermoplastic forming of the surface structure 100.

In an embodiment where the first dielectric pattern 106 has a non-uniform width, the first dielectric pattern 106 in the first region R1 has a first average width w1, the first dielectric pattern 106 in the second region R2 has a second average width w2, and the first average width w1 is different from the second average width w2. Specifically, when the tensile rate or the deformation stress subjected to the first conductive line 104 in the first region R1 is greater than the tensile rate or the deformation stress subjected to the first conductive line 104 in the second region R2, the first average width w1 is greater than the second average width w2. On the contrary, when the tensile rate or the deformation stress subjected to the first conductive line 104 in the first region R1 is less than the tensile rate or the deformation stress subjected to the first conductive line 104 in the second region R2, the first average width w1 is less than the second average width w2. Through the first dielectric pattern 106 contacting the first conductive line 104 having different widths at different positions corresponding to the first conductive line 104, the deformation stress subjected to the first conductive line 104 is buffered and absorbed to reduce the possibility of delamination or breakage of the first conductive line 104. For example, in FIG. 1A, the first region R1 may correspond to a top gentle slope of a convex portion 204 of a molding body 200, and the second region R2 may correspond to a turning point where the convex portion 204 and a flat portion 202 of the molding body 200 meet, so the tensile rate or the deformation stress subjected to the first conductive line 104 in the first region R1 is less than the tensile rate or the deformation stress subjected to the first conductive line 104 in the second region R2. Accordingly, through the second average width w2 of the first dielectric pattern 106 being greater than the first average width w1, the tensile rate or the deformation stress subjected to the first conductive line 104 at different positions can be buffered and absorbed to reduce the possibility of delamination or breakage of the first conductive line 104.

It should be understood that the first region R1 and the second region R2 shown in FIG. 1A are for the convenience of explaining the relationship between the first region R1 and the second region R2, but are not intended to limit the positions of the first region R1 and the second region R2, which are acceptable as long as the tensile rate subjected to the first region R1 is less than the tensile rate subjected to the second region R2 and the tensile rates of the first region R1 and the second region R2 are both greater than or equal to 5%. In addition, although it is shown in FIG. 1B that the first dielectric pattern 106 has a non-uniform width, the same is not intended to limit the disclosure. The first dielectric pattern 106 may also have a uniform width, and the stress subjected to the conductive line is reduced through other manners (such as adjusting the thickness ratio of the dielectric pattern to the conductive line or the routing direction and the tensile direction of the conductive line described below).

In some embodiments, the ratio of the second average width w2 to the first average width w1 is between 1.2 and 8 or between 2 and 5, so that the first dielectric pattern 106 can effectively buffer and absorb the tensile rate or the deformation stress at different positions corresponding to the first conductive line 104.

In some embodiments, the first dielectric pattern 106 has a substantially uniform width (that is, the first average width w1) in the first region R1, but the disclosure is not limited thereto. In other embodiments, the first dielectric pattern 106 may have different widths in the first region R1, such that the first dielectric pattern 106 has the first average width w1 in the first region R1. In some embodiments, the first dielectric pattern 106 has a substantially uniform width (that is, the second average width w2) in the second region R2, but the disclosure is not limited thereto. In other embodiments, the first dielectric pattern 106 may have different widths in the second region R2, such that the first dielectric pattern 106 has the second average width w2 in the second region R2.

In some embodiments, the width of the first dielectric pattern 106 may increment from the first region R1 to the second region R2, but the disclosure is not limited thereto.

In some embodiments, the surface structure 100 also includes the second conductive line 108 disposed on the first dielectric pattern 106. The second conductive line 108 may be similar to the first conductive line 104, such as having the same line width, material, etc., but the disclosure is not limited thereto. In other embodiments, the second conductive line 108 may have a different line width and/or material from the first conductive line 104.

In some embodiments, the first conductive line 106 may completely overlap or partially overlap with the second conductive line 108 in a vertical direction N, and the first dielectric pattern 106 is located at least between a region where the first conductive line 106 overlaps with the second conductive line 108, so that the first conductive line 106 is electrically isolated from the second conductive line 108. In some embodiments, the first dielectric pattern 106 may completely overlap with and directly contact the second conductive line 108, but the disclosure is not limited thereto. In other embodiments, the first dielectric pattern 106 and the second conductive line 108 intersect each other, so that the first dielectric pattern 106 may partially overlap with and directly contact the second conductive line 108. The width of the first dielectric pattern 106 may be greater than the width of the second conductive line 108. A part where the first dielectric pattern 106 overlaps with and directly contacts the second conductive line 108 may provide stress buffering or absorption for the second conductive line 108.

In the embodiment, since the first conductive line 104, the first dielectric pattern 106, and the second conductive line 108 overlap with each other in the vertical direction N, the stress trends subjected to the first conductive line 104 and the second conductive line 108 at various places on the surface structure 100 are similar. For example, the tensile rate or the deformation stress subjected to the first conductive line 104 in the first region R1 is less than the tensile rate or the deformation stress subjected to the first conductive line 104 in the second region R2, and the tensile rate or the deformation stress subjected to the second conductive line 108 in the first region R1 is less than the tensile rate or the deformation stress subjected to the second conductive line 108 in the second region R2, so through changing the width of the first dielectric pattern 106 located between the first conductive line 104 and the second conductive line 108 according to the tensile rate or the deformation stress subjected to the adjacent conductive line (that is, the first conductive line 104 and the second conductive line 108) corresponding thereto, the first dielectric pattern 106 has different widths to improve the buffering or the absorption for the first conductive line 104 and the second conductive line 108 at different stress changing places to reduce the possibility of delamination or breakage of the first conductive line 104 and the second conductive line 108. In other words, the first dielectric pattern 106 may also have different widths at different positions corresponding to the second conductive line 108 to buffer and absorb different deformation stress subjected to the second conductive line 108 to reduce the possibility of delamination or breakage of the second conductive line 108.

In some embodiments, the first conductive line 104 (or the second conductive line 108) has a third average width w3 (marked in FIG. 1C) in the first region R1, the first conductive line 104 (or the second conductive line 108) has a fourth average width w4 (marked in FIG. 1C) in the second region R2, and the ratio of the first average width w1 to the third average width w3 (w1/w3) is different from the ratio of the second average width w2 to the fourth average width w4 (w2/w4).

In some embodiments, the first conductive line 104 (or the second conductive line 108) substantially has a uniform line width, that is, the third average width w3 is substantially equal to the fourth average width w4, but the disclosure is not limited thereto. In other embodiments, the first conductive line 104 (or the second conductive line 108) may have a non-uniform line width. For example, the third average width w3 may be greater than or less than the fourth average width w4.

In an embodiment where the second conductive line 108 only partially overlaps with the first conductive line 104 and the first dielectric pattern 106 in the vertical direction N (for example, the second conductive line 108 intersects the first conductive line 104 and the first dielectric pattern 106), the surface structure 100 may also include a second dielectric pattern (not shown) disposed on the second conductive line 108. The second dielectric pattern may completely overlap with and directly contact the second conductive line 108 and have different widths according to the tensile rate or the deformation stress subjected to the second conductive line 108 at various places, thereby providing corresponding stress buffering or absorption corresponding to different positions of the second conductive line 108 to reduce the possibility of delamination or breakage of the second conductive line 108.

In some embodiments, the orthographic projection shapes of the first conductive line 104 and the second conductive line 108 on the projection surface P are rectilinear shapes, but the disclosure is not limited thereto. In other embodiments, the orthographic projection shapes of the first conductive line 104 and the second conductive line 108 on the projection surface P may respectively include a linear shape, a serpentine shape, an S shape, a horseshoe shape, a wavy shape, a square waveform, or other suitable shapes. The projection surface P refers to, for example, a plane perpendicular to the vertical direction N, that is, from a top view angle.

In some embodiments, the first conductive line 104 and the second conductive line 108 may have the same or different orthographic projection shapes, but the disclosure is not limited thereto.

In some embodiments, the orthographic projection shape of the first dielectric pattern 106 on the projection surface P may roughly correspond to the orthographic projection shape of the first conductive line 104 on the projection surface P. In some embodiments, the orthographic projection shape of the first dielectric pattern 106 on the projection surface P may roughly correspond to the orthographic projection shape of the second conductive line 108 on the projection surface P. In some embodiments, the orthographic projection shape of the first dielectric pattern 106 on the projection surface P may include a linear shape, a serpentine shape, an S shape, a horseshoe shape, a wavy shape, a square waveform, or other suitable shapes, but the disclosure is not limited thereto.

In some embodiments, the ratio of an average thickness t1 of the first dielectric pattern 106 to an average thickness t2 of the first conductive line 104 (that is, t1/t2) and the ratio of the average thickness t1 of the first dielectric pattern 106 to an average thickness t3 of the second conductive line 108 (that is t1/t3) may be respectively between 0.5 and 10 or between 1 and 4. In this way, the stress accumulated on the surface structure 100 during a thermoplastic forming process can be further alleviated to effectively reduce the risk of extrusion delamination.

In some embodiments, the average thickness t3 of the second conductive line 108 may be greater than or equal to the average thickness t2 of the first conductive line 104. In some embodiments, the ratio of the average thickness t3 of the second conductive line 108 to the average thickness t2 of the first conductive line 104 is between 1 and 5.

In some embodiments, the first dielectric pattern 106 may have a uniform thickness, the first conductive line 104 may have a uniform thickness, and the second conductive line 108 may have a uniform thickness, but the disclosure is not limited thereto.

In some embodiments, from a top view angle, as shown in FIG. 1B, a routing direction L of the first conductive line 104 (or the second conductive line 108) is roughly the same as a tensile direction F (that is, a component force direction of a tensile force parallel to the projection surface P) subjected to any point (for example, a point A as shown in FIG. 1B) on the first conductive line 104 (or the second conductive line 108), but the disclosure is not limited thereto. In other embodiments, from a top view angle, as shown in FIG. 1B, the routing direction L of the first conductive line 104 (or the second conductive line 108) is different from the tensile direction F (that is, the component force direction of the tensile force parallel to the projection surface P) subjected to any point on the first conductive line 104 (or the second conductive line 108). In the disclosure, the routing direction L refers to the main extension direction of the conductive line as a whole; and the tensile direction F refers to the direction of the total tensile force subjected to the point.

In some embodiments, the electronic device 10 may also include the molding body 200. The surface structure 100 may be disposed on the molding body 200 in the vertical direction N. The morphology of the surface structure 100 may correspond to the morphology of a surface 200s of the molding body 200. In other words, the surface structure 100 may extend along the surface 200s of the molding body 200. In some embodiments, the first surface 102a of the substrate 102 faces the surface 200s of the molding body 200, and the second surface 102b of the substrate 102 faces away from the molding body 200 and is exposed to the external environment. In other words, the first conductive line 104 is disposed between the substrate 102 and the molding body 200, and the first dielectric pattern 106 is disposed between the first conductive line 104 and the molding body 200. However, the disclosure is not limited thereto. In other embodiments, the second surface 102b of the substrate 102 may face the surface 200s of the molding body 200, and the first surface 102a of the substrate 102 may face away from the molding body 200.

In some embodiments, the molding body 200 may be in various three-dimensional shapes, such as a cuboid, a cube, a sphere, a hemisphere, a ring, a cylinder, a combination thereof, or other suitable three-dimensional shapes, but the disclosure is not limited thereto.

In some embodiments, the molding body 200 may have a convex portion or a concave portion. For example, as shown in FIG. 1A, the molding body 200 may include the flat portion 202 and the convex portion 204 located on the flat portion 202. The convex portion 204 may be, for example, a cuboid or in other suitable shapes, so that the surface 200s of the molding body 200 has a convex surface corresponding to the convex portion 204. The surface structure 100 extends along the flat portion 202 and the convex portion 204 of the molding body 200, so that the surface structure 100 has a morphology corresponding to the flat portion 202 and the convex portion 204 along with the molding body 200. In some embodiments, the surface structure 100 is stretched (such as by performing a thermoplastic forming process through using a corresponding mold) to form a morphology that corresponds to and matches the surface 200s of the molding body 200.

The molding body 200 may include a thermoplastic material, including, for example, epoxy resin, polyurethane (PU), polycarbonate (PC), polyethylene (PE), polyethylene terephthalate (PET), polypropylene (PP), acrylonitrile-butadiene-styrene (ABS) resin, polymethyl methacrylate (PMMA), a combination thereof, or other suitable molding materials.

In some embodiments, the substrate 102 may be a flexible substrate. The material of the substrate 102 may be selected from a group composed of polyethylene terephthalate (PET), polyethylene terephthalate-1,4-cyclohexane dimethanol (PETG), polycarbonate (PC), polyimide (PI), polymethyl methacrylate (PMMA), polyphenylene ether styrene (PES), polydimethylsiloxane (PDMS), ABS resin, and acrylic resin. In some embodiments, the Young's modulus of the substrate 102 may be between 0.5 GPa and 20 GPa. In some embodiments, the thickness of the substrate 102 may be between 0.1 mm and 5 mm, but the disclosure is not limited thereto.

In some embodiments, the first dielectric pattern 106 may be made of an insulating material with stretchability, compressibility, or plasticity to provide stress buffering or absorption for the corresponding conductive line (for example, the first conductive line 104 or the second conductive line 108) when the surface structure 100 is deformed. For example, the material of the first dielectric pattern 106 may be selected from a group composed of acrylic resin, epoxy resin, phenolic resin, polyester resin, polyurethane resin, silicone resin, polyimide, and a solution gas barrier (SGB) material. The solution gas barrier material may include a polysiloxane compound, such as a compound containing Si—O—C and Si—O—Si bonds. In some embodiments, the dielectric coefficient of the first dielectric pattern 106 may be greater than 3.9.

In some embodiments, the materials of the first conductive line 104 and the second conductive line 108 may respectively include gold, silver, copper, aluminum, nickel, tin, an alloy thereof, a combination thereof, or other suitable conductive materials.

In some embodiments, the surface structure 100 may also include an electronic element (not shown), such as a resistor, a capacitor, or other suitable electronic elements, but the disclosure is not limited thereto. The electronic element may be disposed on the first surface 102a or the second surface 102b of the substrate 102 and is electrically connected to the corresponding conductive line (for example, the first conductive line 104 or the second conductive line 108) in the surface structure 100. In some embodiments, the electronic element may be a surface mount device.

FIG. 1A to FIG. 1C schematically illustrate the surface structure 100 including two conductive lines (that is, the first conductive line 104 and the second conductive line 108) and one dielectric pattern (that is, the first dielectric pattern 106), but are not intended to limit the disclosure. The surface structure 100 may include more staggered stacked conductive lines and dielectric patterns, which may be adjusted according to actual requirements.

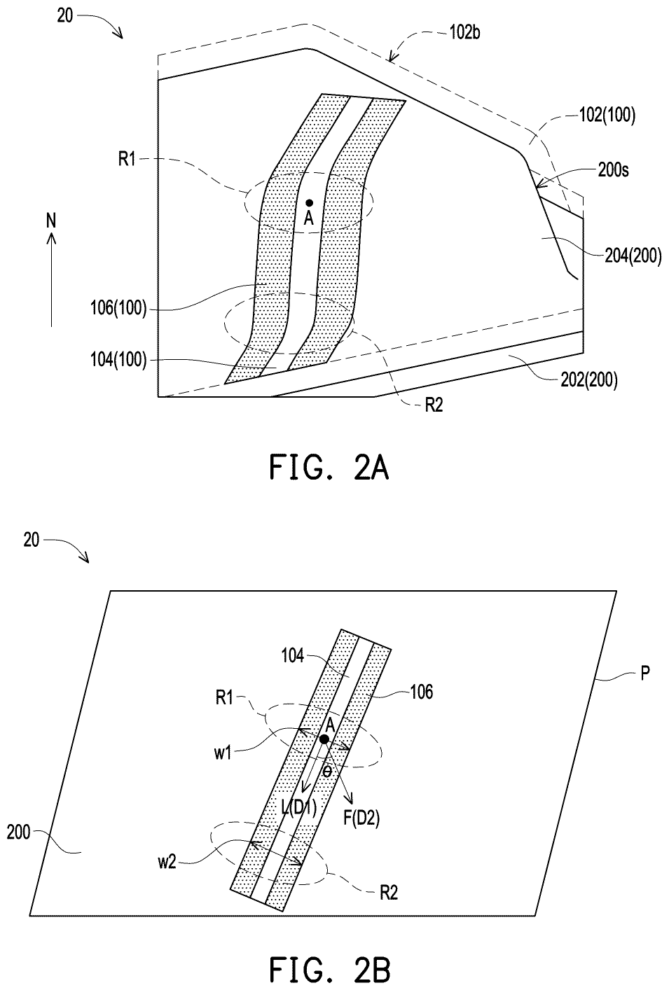

FIG. 2A is a schematic three-dimensional view of an electronic device 20 according to an embodiment of the disclosure. FIG. 2B is a schematic top view of the electronic device 20 according to an embodiment of the disclosure. The embodiment of FIG. 2A and FIG. 2B continues to use the reference numerals and some content of the embodiment of FIG. 1A to FIG. 1C, wherein the same or similar numerals are adopted to represent the same or similar elements, and the description of the same technical content is omitted. For the description of the omitted part, reference may be made to the foregoing embodiment and will not be elaborated here. FIG. 2B may be a partial schematic top view of FIG. 2A and may also be regarded as the orthographic projection of the electronic device 20 on the projection surface P. For clarity of illustration, the substrate 102 is omitted in FIG. 2B, and the omitted part may be understood with reference to FIG. 2A.

Please refer to FIG. 2A and FIG. 2B. The difference between the electronic device 20 and the electronic device 10 is that from a top view angle, the routing direction L of the first conductive line 104 (or the second conductive line 108) of the electronic device 20 is different from the tensile direction F (that is, the component force direction of the tensile force parallel to the projection surface P) subjected to any point on the first conductive line 104 (or the second conductive line 108). For example, the orthographic projection of the routing direction L of the first conductive line 104 on the projection surface P extends in a first direction D1, the orthographic projection of the tensile direction F subjected to the first conductive line 104 at the point A on the projection surface P extends in a second direction D2, and the second direction D2 is different from the first direction D1. Similarly, the orthographic projection of the routing direction L of the second conductive line 108 on the projection surface P may extend in the first direction D1, the orthographic projection of the tensile direction F subjected to the second conductive line 104 corresponding to the point A on the projection surface P may extend in the second direction D2, and the second direction D2 is different from the first direction D1. In this way, the tensile rate or the deformation stress subjected to the conductive line can be alleviated, thereby reducing the risk of delamination or breakage of the conductive line.

In some embodiments, there is an included angle θ between the second direction D2 and the first direction D1, and the included angle θ may be between 15 degrees and 75 degrees or between 105 degrees and 165 degrees. In this way, the stress accumulated on the surface structure 100 during the thermoplastic molding process can be effectively alleviated to effectively reduce the risk such as extrusion delamination and line breakage. In some embodiments, the included angle θ is not 0 degrees, 90 degrees, or 180 degrees.

In some embodiments, from a top view, the first dielectric pattern 106 also extends along the first direction D1. In other words, there may also be the included angle θ between the extension direction of the first dielectric pattern 106 on the projection surface P (that is, the first direction D1) and the second direction D2, and the included angle θ may be between 15 degrees and 75 degrees or between 105 degrees and 165 degrees.

In some embodiments, the first dielectric pattern 106 may have a uniform width, that is, the first average width w1 is equal to the second average width w2. However, the disclosure is not limited thereto. The first dielectric pattern 106 may also have a non-uniform width as shown in the embodiment of FIG. 1A to FIG. 1C to further provide corresponding stress buffering or absorption for the tensile rate or the deformation stress subjected to the first conductive line 104 and the second conductive line 108 at different positions.

In some embodiments, the ratio of the average thickness of the first dielectric pattern 106 to the average thickness of the first conductive line 104 and the ratio of the average thickness of the first dielectric pattern 106 to the average thickness of the second conductive line 108 may be respectively between 0.5 and 10 or between 1 and 4. In this way, the stress accumulated on the surface structure 100 during the thermoplastic molding process can be further alleviated to effectively reduce the risk such as extrusion delamination and line breakage. However, the disclosure is not limited thereto. In other embodiments, the ratio of the average thickness of the first dielectric pattern 106 to the average thickness of the first conductive line 104 or the second conductive line 108 may be other values.

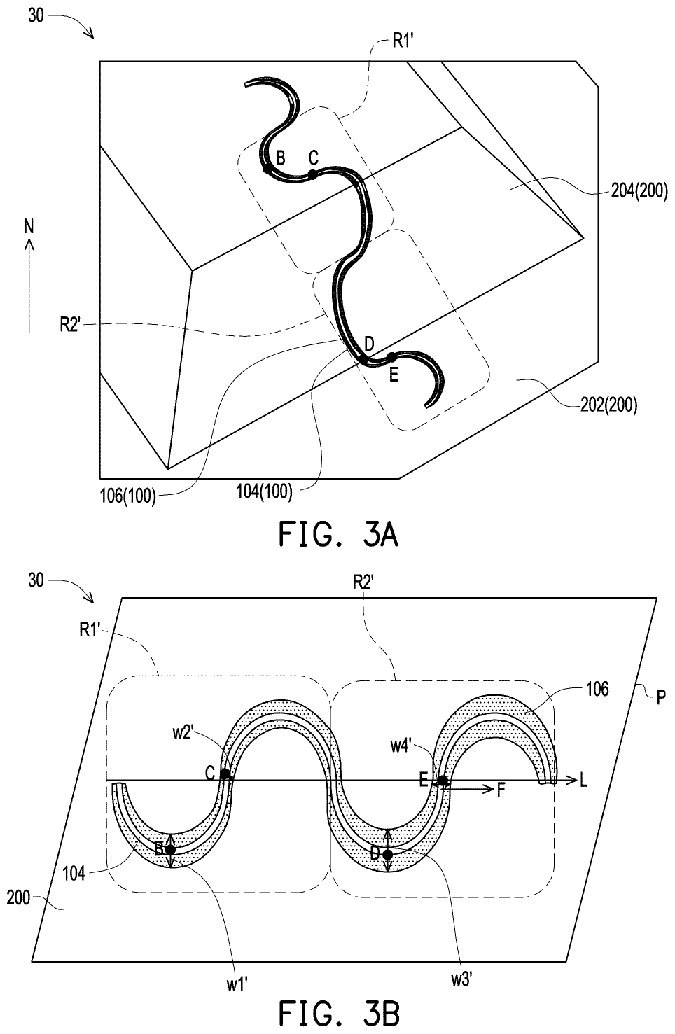

FIG. 3A is a partial schematic three-dimensional view of an electronic device 30 according to an embodiment of the disclosure. FIG. 3B is a partial schematic top view of the electronic device 30 according to an embodiment of the disclosure. The embodiment of FIG. 3A and FIG. 3B continues to use the reference numerals and some content of the embodiment of FIG. 1A to FIG. 1C, wherein the same or similar numerals are adopted to represent the same or similar elements, and the description of the same technical content is omitted. For the description of the omitted part, reference may be made to the foregoing embodiments and will not be elaborated here. FIG. 3B may be a partial schematic top view of FIG. 3A and may also be regarded as the orthographic projection of the electronic device 30 on the projection surface P. For clarity of illustration, the substrate 102 is omitted in FIG. 3A and FIG. 3B, and the omitted part may be understood with reference to FIG. 1A.

Please refer to FIG. 3A and FIG. 3B. The difference between the electronic device 30 and the electronic device 10 is that the orthographic projection shapes of the first conductive line 104 and the second conductive line 108 of the electronic device 30 on the projection surface P are S shapes or wavy shapes. In some embodiments, the orthographic projection shapes of the first conductive line 104 and the second conductive line 108 on the projection surface P may be sinusoidal waveforms. The orthographic projection shape of the first dielectric pattern 106 on the projection surface P roughly corresponds to the first conductive line 104 and the second conductive line 108, and thus also has an S shape or a wavy shape.

In some embodiments, the surface structure 100 of the electronic device 30 has a first region R1′ and a second region R2′, and the tensile rate or the deformation stress subjected to the first conductive line 104 in the first region R1′is less than the tensile rate or the deformation stress subjected to the first conductive line 104 in the second region R2′, such that a second average width of the first dielectric pattern 106 in the second region R2′ is greater than a first average width of the first dielectric pattern 106 in the first region R1′, so that the tensile rate or the deformation stress subjected to the first conductive line 104 at different positions is buffered and absorbed, and the possibility of delamination or breakage of the first conductive line 104 is reduced.

In some embodiments, the first region R1′ is, for example, a region of one sinusoidal wave cycle corresponding to the first conductive line 104 at a convex portion of the surface structure 100 (also corresponding to a top turning point of the convex portion 204 of the molding body 200); and the second region R2′ is, for example, a region one of sinusoidal wave cycle corresponding to the first conductive line 104 at a junction of the convex portion and a flat portion of the surface structure 100 (also corresponding to a junction of the convex portion 204 and the flat portion 202 of the molding body 200). In this case, the tensile rate or the deformation stress subjected to the first conductive line 104 in the first region R1′ is less than the tensile rate or the deformation stress subjected to the first conductive line 104 in the second region R2′, such that the second average width of the first dielectric pattern 106 is greater than the first average width of the first dielectric pattern 106, so that the tensile rate or the deformation stress subjected to the first conductive line 104 in different regions is buffered and absorbed to reduce the possibility of delamination or breakage of the first conductive line 104. Here, the sinusoidal wave cycle refers to a waveform starting from the equilibrium position, passing through the peak, the equilibrium position, and the trough, and then returning to the equilibrium position.

In some embodiments, the width of the first dielectric pattern 106 in the first region R1′ and/or the width in the second region R2′ is a non-uniform width. For one sinusoidal wave cycle of the first conductive line 104, taking the first region R1′ as an example, the tensile rate or the deformation stress subjected to the first conductive line 104 corresponding to the equilibrium position (for example, a point C in FIG. 3B) of the sinusoidal waveform is less than the tensile rate or the deformation stress subjected to the first conductive line 104 corresponding to the peak or the trough (for example, a point B in FIG. 3B) of the sinusoidal waveform. Therefore, a width w2′ of the first dielectric pattern 106 corresponding to the equilibrium position (for example, the point C in FIG. 3B) of the sinusoidal waveform of the first conductive line 104 may be less than a width w1′ of the first dielectric pattern 106 corresponding to the peak or the trough (for example, the point B in FIG. 3B) of the sinusoidal waveform of the first conductive line 104, so that the tensile rate or the deformation stress subjected to the first conductive line 104 at different positions in the first region R1′ is correspondingly buffered and absorbed. Similarly, in the second region R2′, the tensile rate or the deformation stress subjected to the first conductive line 104 corresponding to the equilibrium position (for example, a point E in FIG. 3B) of the sinusoidal waveform is less than the tensile rate or the deformation stress subjected to the first conductive line 104 corresponding to the peak or the trough (for example, a point D in FIG. 3B) of the sinusoidal waveform. Therefore, a width w4′ of the first dielectric pattern 106 corresponding to the equilibrium position (for example, the point E in FIG. 3B) of the sinusoidal waveform of the first conductive line 104 may be less than a width w3′ of the first dielectric pattern 106 corresponding to the peak or the trough (for example, the point D in FIG. 3B) of the sinusoidal waveform of the first conductive line 104, so that the tensile rate or the deformation stress subjected to the first conductive line 104 at different positions in the second region R2′ is correspondingly buffered and absorbed.

In some embodiments, the width w1′ of the first dielectric pattern 106 corresponding to the peak or the trough (for example, the point B in FIG. 3B) of the sinusoidal waveform of the first conductive line 104 in the first region R1′ is less than the width w3′ of the first dielectric pattern 106 corresponding to the peak or the trough (for example, the point D in FIG. 3B) of the sinusoidal waveform of the first conductive line 104 in the second region R2′; and the width w2′ of the first dielectric pattern 106 corresponding to the equilibrium position (for example, the point C in FIG. 3B) of the sinusoidal waveform of the first conductive line 104 in the first region R1′is less than the width w4′ of the first dielectric pattern 106 corresponding to the equilibrium position (for example, the point E in FIG. 3B) of the sinusoidal waveform of the first conductive line 104 in the second region R2′.

In some embodiments, when the tensile rate or the deformation stress subjected to the first conductive line 104 in the first region R1′ is less than the tensile rate or the deformation stress subjected to the first conductive line 104 in the second region R2′, the ratio of the width w1′ of the first dielectric pattern 106 corresponding to the peak or the trough (for example, the point B in FIG. 3B) of the sinusoidal waveform of the first conductive line 104 in the first region R1′ to the width w2′ of the first dielectric pattern 106 corresponding to the equilibrium position (for example, the point C in FIG. 3B) of the sinusoidal waveform of the first conductive line 104 in the first region R1′ (that is, w1′/w2′) is less than the ratio of the width w3′ of the first dielectric pattern 106 corresponding to the peak or the trough (for example, the point D in FIG. 3B) of the sinusoidal waveform of the first conductive line 104 in the second region R2′ to the width w4′ of the first dielectric pattern 106 corresponding to the equilibrium position (for example, the point E in FIG. 3B) of the sinusoidal waveform of the first conductive line 104 in the second region R2′ (that is, w3′/w4′). On the contrary, when the tensile rate or the deformation stress subjected to the first conductive line 104 in the first region R1′ is greater than or equal to the tensile rate or the deformation stress subjected to the first conductive line 104 in the second region R2′, the ratio of the width w1′ of the first dielectric pattern 106 corresponding to the peak or the trough (for example, the point B in FIG. 3B) of the sinusoidal waveform of the first conductive line 104 in the first region R1′ to the width w2′ of the first dielectric pattern 106 corresponding to the equilibrium position (for example, the point C in FIG. 3B) of the sinusoidal waveform of the first conductive line 104 in the first region R1′ (that is, w1′/w2′) is greater than or equal to the ratio of the width w3′ of the first dielectric pattern 106 corresponding to the peak or the trough (for example, the point D in FIG. 3B) of the sinusoidal waveform of the first conductive line 104 in the second region R2′ to the width w4′ of the first dielectric pattern 106 corresponding to the equilibrium position (for example, the point E in FIG. 3B) of the sinusoidal waveform of the first conductive line 104 in the second region R2′ (that is, w3′/w4′).

It should be understood that the above content takes the first conductive line 104 as an example to describe the relationship between the first conductive line 104 and the first dielectric pattern 106, and the same applies to the relationship between the second conductive line 108 and the first dielectric pattern 106. In addition, the first region R1′ and the second region R2′ shown in FIG. 3A and FIG. 3B are for the convenience of explaining the relationship between the first region R1′ and the second region R2′, but are not intended to limit the positions of the first region R1′ and the second region R2′, which are acceptable as long as the tensile rate subjected to the first region R1′ is less than the tensile rate subjected to the second region R2′ and the tensile rates of the first region R1′ and the second region R2′ are both greater than or equal to 5%.

In some embodiments, the ratio of the average thickness of the first dielectric pattern 106 to the average thickness of the first conductive line 104 and the ratio of the average thickness of the first dielectric pattern 106 to the average thickness of the second conductive line 108 may be respectively between 0.5 and 10 or between 1 and 4. In this way, the stress accumulated on the surface structure 100 during the thermoplastic molding process can be further alleviated to effectively reduce the risk such as extrusion delamination and line breakage. However, the disclosure is not limited thereto. In other embodiments, the ratio of the average thickness of the first dielectric pattern 106 to the average thickness of the first conductive line 104 or the second conductive line 108 may be other values.

In some embodiments, from a top view angle, as shown in FIG. 3B, the routing direction L of the first conductive line 104 (or the second conductive line 108) may be roughly the same as the tensile direction F (that is, the component force direction of the tensile force parallel to the projection surface P) subjected to any point (for example, the point E shown in FIG. 3B) on the first conductive line 104 (or the second conductive line 108). However, in other embodiments, the routing direction L of the first conductive line 104 (or the second conductive line 108) may also be different from the tensile direction F (that is, the component force direction of the tensile force parallel to the projection surface P) subjected to any point (for example, the point E shown in FIG. 3B) on the first conductive line 104 (or the second conductive line 108), as shown in the embodiment shown in FIG. 2A and FIG. 2B. In the disclosure, the routing direction L of the conductive line refers to the main extension direction of the conductive line as a whole. Therefore, for the embodiment, the routing direction L is roughly the connection direction of the equilibrium position of the sinusoidal waveform of the conductive line.

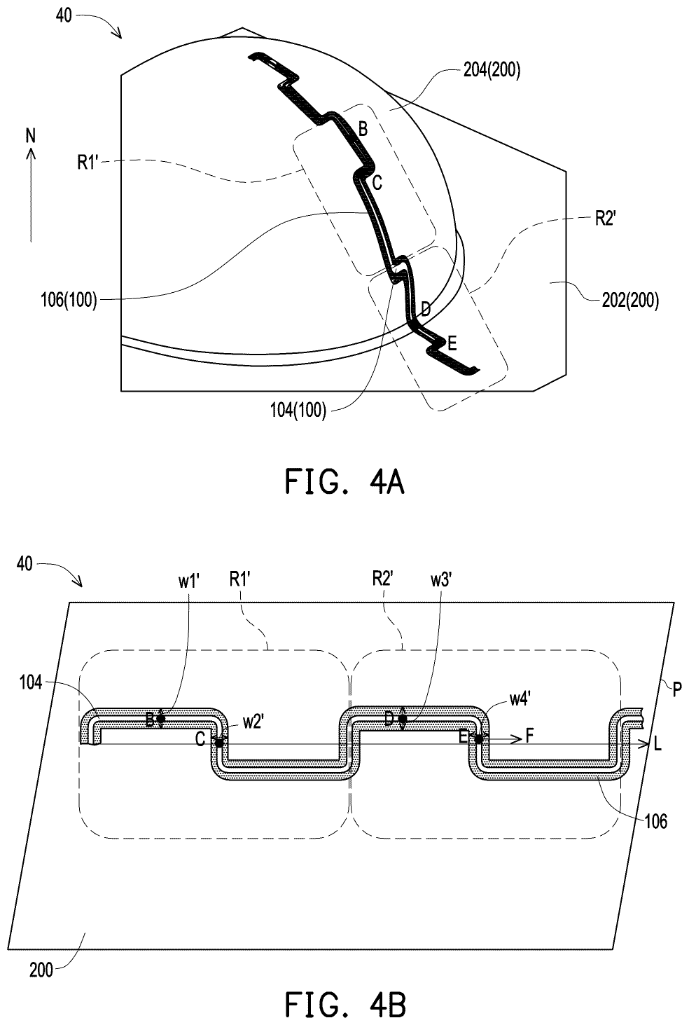

FIG. 4A is a partial schematic three-dimensional view of an electronic device 40 according to an embodiment of the disclosure. FIG. 4B is a partial schematic top view of the electronic device 40 according to an embodiment of the disclosure. The embodiment of FIG. FIG. 4A and 4B continues to use the reference numerals and some content of the embodiment of FIG. 3A and FIG. 3B, wherein the same or similar numerals are adopted to represent the same or similar elements, and the description of the same technical content is omitted. For the description of the omitted part, reference may be made to the foregoing embodiments and will not be elaborated here. FIG. 4B may be a partial schematic top view of FIG. 4A and may also be regarded as the orthographic projection of the electronic device 40 on the projection surface P. For clarity of illustration, the substrate 102 is omitted in FIG. 4A and FIG. 4B, and the omitted part may be understood with reference to FIG. 1A.

Please refer to FIG. 4A and FIG. 4B. The difference between the electronic device 40 and the electronic device 30 is that the orthographic projection shapes of the first conductive line 104 and the second conductive line 108 of the electronic device 40 on the projection surface P are square waveforms. The orthographic projection shape of the first dielectric pattern 106 on the projection surface P roughly corresponds to the first conductive line 104 and the second conductive line 108, and thus also has a square waveform. The convex portion 204 of the molding body 200 of the electronic device 40 is, for example, a hemisphere, but the disclosure is not limited thereto.

In the embodiment, the first region R1′ is, for example, a region of one square wave cycle corresponding to the first conductive line 104 at the convex portion of the surface structure 100 (also corresponding to a hemispherical sidewall of the convex portion 204 of the molding body 200); and the second region R2′ is, for example, a region of one square wave cycle corresponding to the first conductive line 104 at the junction of the convex portion and the flat portion of the surface structure 100 (also corresponding to the junction of the convex portion 204 and the flat portion 202 of the molding body 200). In this case, the tensile rate or the deformation stress subjected to the first conductive line 104 in the first region R1′ is less than the tensile rate or the deformation stress subjected to the first conductive line 104 in the second region R2′, such that the second average width of the first dielectric pattern 106 is greater than the first average width of the first dielectric pattern 106, so that the tensile rate or the deformation stress subjected to the first conductive line 104 in different regions is buffered and absorbed to reduce the possibility of delamination or breakage of the first conductive line 104. Here, the square wave cycle refers to a square wave reaching the highest point (such as opposite to the upper side of FIG. 4B) of the waveform from the equilibrium position, then extending for a certain distance and then reaching the lowest point (such as opposite to the lower side of FIG. 4B) of the waveform via the equilibrium position, and then returning to the equilibrium position after extending for a certain distance from the lowest position.

In some embodiments, the width of the first dielectric pattern 106 in the first region R1′ and/or the width in the second region R2′ is a non-uniform width. For one square wave cycle of the first conductive line 104, taking the first region R1′ as an example, the tensile rate or the deformation stress subjected to the first conductive line 104 corresponding to the equilibrium position (for example, a point C in FIG. 4B) of the square waveform is less than the tensile rate or the deformation stress subjected to the first conductive line 104 corresponding to the highest point or the lowest point (for example, a point B in FIG. 4B) of the square waveform. Therefore, the width w2′ of the first dielectric pattern 106 corresponding to the equilibrium position (for example, the point C in FIG. 4B) of the square waveform of the first conductive line 104 may be less than the width w1′ of the first dielectric pattern 106 corresponding to the highest point or the lowest point (for example, the point B in FIG. 4B) of the square waveform of the first conductive line 104, so that the tensile rate or the deformation stress subjected to the first conductive line 104 at different positions in the first region R1′ is buffered and absorbed. Similarly, in the second region R2′, the tensile rate or the deformation stress subjected to the first conductive line 104 corresponding to the equilibrium position (for example, a point E in FIG. 4B) of the square waveform is less than the tensile rate or the deformation stress subjected to the first conductive line 104 corresponding to the highest point or the lowest point (for example, a point D in FIG. 4B) of the square waveform. Therefore, the width w4′ of the first dielectric pattern 106 corresponding to the equilibrium position (for example, the point E in FIG. 4B) of the square waveform of the first conductive line 104 may be less than the width w3′ of the first dielectric pattern 106 corresponding to the highest point or the lowest point (for example, the point D in FIG. 4B) of the square waveform of the first conductive line 104, so that the tensile rate or the deformation stress subjected to the first conductive line 104 at different positions in the second region R2′ is buffered and absorbed.

In some embodiments, the width w1′ of the first dielectric pattern 106 corresponding to the highest point or the lowest point (for example, the point B in FIG. 4B) of the square waveform of the first conductive line 104 in the first region R1′ is less than the width w3′ of the first dielectric pattern 106 corresponding to at the highest point or the lowest point (for example, the point D in FIG. 4B) of the square waveform of the first conductive line 104 in the second region R2′; and the width w2′ of the first dielectric pattern 106 corresponding to the equilibrium position (for example, the point C in FIG. 4B) of the square waveform of the first conductive line 104 in the first region R1′ is less than the width w4′ of the first dielectric pattern 106 corresponding to the equilibrium position (for example, the point E in FIG. 4B) of the square waveform of the first conductive line 104 in the second region R2′.

In some embodiments, when the tensile rate or the deformation stress subjected to the first conductive line 104 in the first region R1′ is less than the tensile rate or the deformation stress subjected to the first conductive line 104 in the second region R2′, the ratio of the width w1′ of the first dielectric pattern 106 corresponding to the highest point or the lowest point (for example, the point B in FIG. 4B) of the square waveform of the first conductive line 104 in the first region R1′ to the width w2′ of the first dielectric pattern 106 corresponding to the equilibrium position (for example, the point C in FIG. 4B) of the square waveform of the first conductive line 104 in the first region R1′ (that is, w1′/w2′) is less than the ratio of the width w3′ of the first dielectric pattern 106 corresponding to the highest point or the lowest point (for example, the point D in FIG. 4B) of the square waveform of the first conductive line 104 in the second region R2′ to the width w4′ of the first dielectric pattern 106 corresponding to the equilibrium position (for example, the point E in FIG. 4B) of the square waveform of the first conductive line 104 in the second region R2′ (that is, w3′/w4′). On the contrary, when the tensile rate or the deformation stress subjected to the first conductive line 104 in the first region R1′ is greater than or equal to the tensile rate or the deformation stress subjected to the first conductive line 104 in the second region R2′, the ratio of the width w1′ of the first dielectric pattern 106 corresponding to the highest point or the lowest point (for example, the point B in FIG. 4B) of the square waveform of the first conductive line 104 in the first region R1′ to the width w2′ of the first dielectric pattern 106 corresponding to the equilibrium position (for example, the point C in FIG. 4B) of the square waveform of the first conductive line 104 in the first region R1′ (that is, w1′/w2′) is greater than or equal to the ratio of the width w3′ of the first dielectric pattern 106 corresponding to the highest point or the lowest point (for example, the point D in FIG. 4B) of the square waveform of the first conductive line 104 in the second region R2′ to the width w4′ of the first dielectric pattern 106 corresponding to the equilibrium position (for example, the point E in FIG. 4B) of the square waveform of the first conductive line 104 in the second region R2′ (that is, w3′/w4′).

It should be understood that the above content takes the first conductive line 104 as an example to describe the relationship between the first conductive line 104 and the first dielectric pattern 106, and the same applies to the relationship between the second conductive line 108 and the first dielectric pattern 106. In addition, the first region R1′ and the second region R2′ shown in FIG. 4A and FIG. 4B are for the convenience of explaining the relationship between the first region R1′ and the second region R2′, but are not intended to limit the positions of the first region R1′ and the second region R2′, which are acceptable as long as the tensile rate subjected to the first region R1′ is less than the tensile rate subjected to the second region R2′ and the tensile rates of the first region R1′ and second region R2′ are both greater than or equal to 5%.

In some embodiments, the ratio of the average thickness of the first dielectric pattern 106 to the average thickness of the first conductive line 104 and the ratio of the average thickness of the first dielectric pattern 106 to the average thickness of the second conductive line 108 may be respectively between 0.5 and 10 or between 1 and 4. In this way, the stress accumulated on the surface structure 100 during the thermoplastic molding process can be further alleviated to effectively reduce the risk such as extrusion delamination and line breakage. However, the disclosure is not limited thereto. In other embodiments, the ratio of the average thickness of the first dielectric pattern 106 to the average thickness of the first conductive line 104 or the second conductive line 108 may be other values.

In some embodiments, from a top view angle, as shown in FIG. 4B, the routing direction L of the first conductive line 104 (or the second conductive line 108) may be roughly the same as the tensile direction F (that is, the component force direction of the tensile force parallel to the projection surface P) subjected to any point (for example, the point E shown in FIG. 4B) on the first conductive line 104 (or the second conductive line 108). However, in other embodiments, the routing direction L of the first conductive line 104 (or the second conductive line 108) may also be different from the tensile direction F (that is, the component force direction of the tensile force parallel to the projection surface P) subjected to any point (for example, the point E shown in FIG. 4B) on the first conductive line 104 (or the second conductive line 108), as shown in the embodiment shown in FIG. 2A and FIG. 2B. In the disclosure, the routing direction L of the conductive line refers to the main extension direction of the conductive line as a whole. Therefore, for the embodiment, the routing direction L is roughly the connection direction of the equilibrium position of the square waveform of the conductive line.

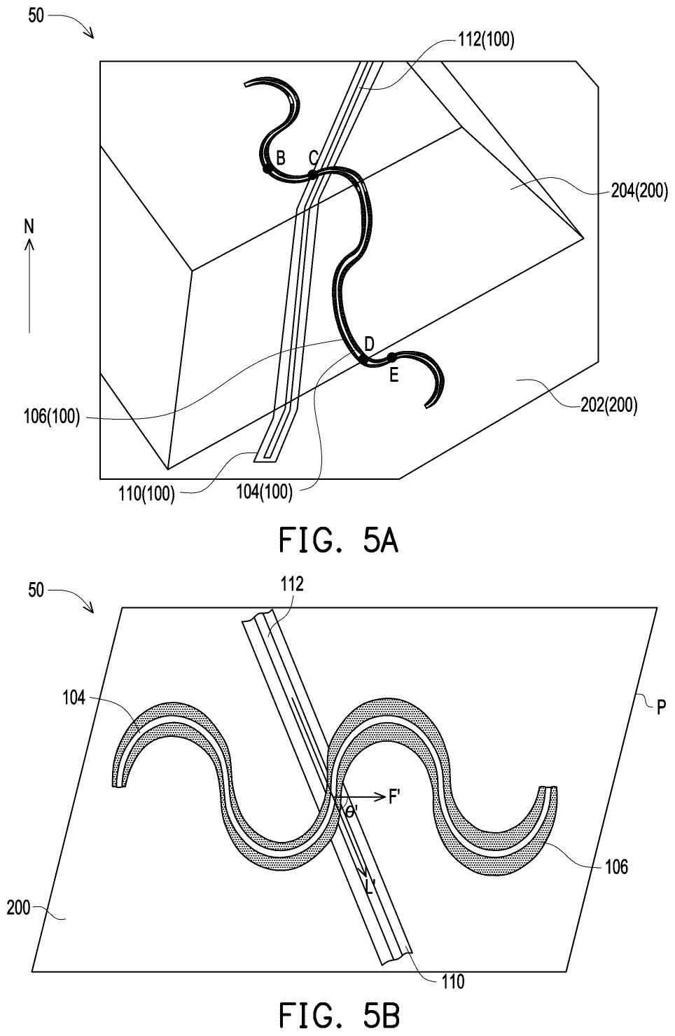

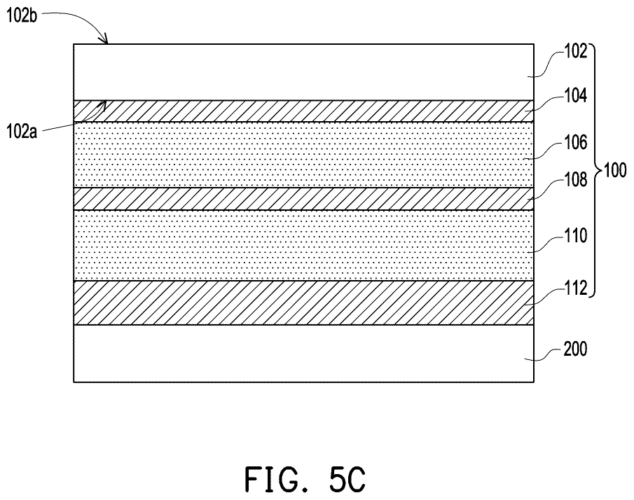

FIG. 5A is a partial schematic three-dimensional view of an electronic device 50 according to an embodiment of the disclosure. FIG. 5B is a partial schematic top view of the electronic device 50 according to an embodiment of the disclosure. FIG. 5C is a partial schematic cross-sectional view of the electronic device 50 according to an embodiment of the disclosure. The embodiment of FIG. 5A to FIG. 5C continues to use the reference numerals and some content of the embodiment of FIG. 3A and FIG. 3B, wherein the same or similar numerals are adopted to represent the same or similar elements, and the description of the same technical content is omitted. For the description of the omitted part, reference may be made to the foregoing embodiments and will not be elaborated here. FIG. 5B may be a partial schematic top view of FIG. 5A and may also be regarded as the orthographic projection of the electronic device 50 on the projection surface P. FIG. 5C may be a schematic cross-sectional view of an intersection of the first conductive line 104 and the second conductive line 108 and a third conductive line 112. For clarity of illustration, the substrate 102 is omitted in FIG. 5A and FIG. 5B, and the omitted part may be understood with reference to FIG. 1A.

Please refer to FIG. 5A, FIG. 5B, and FIG. 5C. The difference between the electronic device 50 and the electronic device 30 is that the surface structure 100 of the electronic device 50 includes the first conductive line 104, the first dielectric pattern 106, the second conductive line 108, a second dielectric pattern 110, and the third conductive line 112 that are sequentially disposed above the first surface 102a of the substrate 102, wherein the third conductive line 112 intersects the first conductive line 104 and the second conductive line 108. The surface structure 100 faces a surface of the molding body 200 with the first surface 102a of the substrate 102 and is disposed on the molding body 200 in the vertical direction N. The relevant configurations related to the first dielectric pattern 106 and the first conductive line 104 and the second conductive line 108 may be similar to the configurations in the embodiment of FIG. 3A and FIG. 3B or also other configurations (for example, in the embodiment of FIG. 1A to FIG. 1C, FIG. 2A and FIG. 2B, or FIG. 4A and FIG. 4B). The material of the second dielectric pattern 110 may be similar to the first dielectric pattern 106, and the material of the third conductive line 112 may be similar to the first conductive line 104 or the second conductive line 108. A part of the second dielectric pattern 110 may be located between the second conductive line 108 and the third conductive line 112 and contact the second conductive line 108 and the third conductive line 112, and another part may be located between the substrate 102 and the third conductive line 112 and contact the substrate 102 and third conductive line 112. In some embodiments, the second dielectric pattern 110 completely overlaps with and directly contacts the third conductive line 112.

In some embodiments, the second dielectric pattern 110 may have different widths according to the tensile rate or the deformation stress subjected to the third conductive line 112 at various places, similar to the embodiment of FIG. 1A to FIG. 1C, to provide corresponding stress buffering or absorption for the third conductive line 112 at various places, thereby reducing the possibility of delamination or breakage of the third conductive line 112. However, the disclosure is not limited thereto. In other embodiments, the second dielectric pattern 110 may have a uniform width, similar to the embodiment of FIG. 2A and FIG. 2B.

In some embodiments, the ratio of the thickness of the second dielectric pattern 110 to the thickness of the third conductive line 112 may be between 0.5 and 10 or between 1 and 4. In this way, the stress accumulated on the surface structure 100 during the thermoplastic molding process can be alleviated to effectively reduce the risk such as extrusion delamination and line breakage. However, the disclosure is not limited thereto. In other embodiments, the ratio of the thickness of the second dielectric pattern 110 to the thickness of the third conductive line 112 may be less than 0.5 or greater than 10.

In some embodiments, the ratio of the thickness of the second dielectric pattern 110 to the thickness of the second conductive line 108 may be between 0.5 and 10 or between 1 and 4. In this way, stress buffering or absorption may be further provided for a part of the second conductive line 108 contacting the second dielectric pattern 110 to reduce the risk such as extrusion delamination and line breakage. However, the disclosure is not limited thereto. In other embodiments, the ratio of the thickness of the second dielectric pattern 110 to the thickness of the second conductive line 108 may be less than 0.5 or greater than 10.

In some embodiments, the thickness of a conductive line layer (that is, the third conductive line 112) closest to the molding body 200 in the surface structure 100 may be greater than the first conductive line 104 and the second conductive line 108.

In some embodiments, from a top view angle, as shown in FIG. 5B, a routing direction L′ of the third conductive line 112 may be roughly the same as a tensile direction F′ (that is, a component force direction of a tensile force parallel to the projection surface P) subjected to any point on the second conductive line 112. However, in other embodiments, the routing direction L′ of the third conductive line 112 may also be different from the tensile direction F′ (that is, the component force direction of the tensile force parallel to the projection surface P) subjected to any point on the third conductive line 112, as shown in the embodiment shown in FIG. 2A and FIG. 2B. In some embodiments, from a top view angle, there is an included angle θ′ between the routing direction L′ of the third conductive line 112 and the tensile direction F′ subjected to any point on the third conductive line 112, and the included angle θ′ is between 15 degrees and 75 degrees or between 105 degrees and 165 degrees. In this way, the stress accumulated on the surface structure 100 during the thermoplastic molding process can be alleviated to effectively reduce the risk such as extrusion delamination and line breakage.

FIG. 5A to FIG. 5C schematically illustrate the surface structure 100 including three conductive lines (that is, the first conductive line 104, the second conductive line 108, and the third conductive line 112) and two dielectric patterns (that is, the first dielectric pattern 106 and the second dielectric pattern 110), but are not intended to limit the disclosure. The surface structure 100 may include more staggered stacked conductive lines and dielectric patterns, and adjacent conductive lines and dielectric patterns may be configured as shown in the embodiment FIG. 1A to FIG. 1C, FIG. 2A and FIG. 2B, FIG. 3A and FIG. 3B, or FIG. 4A and FIG. 4B.

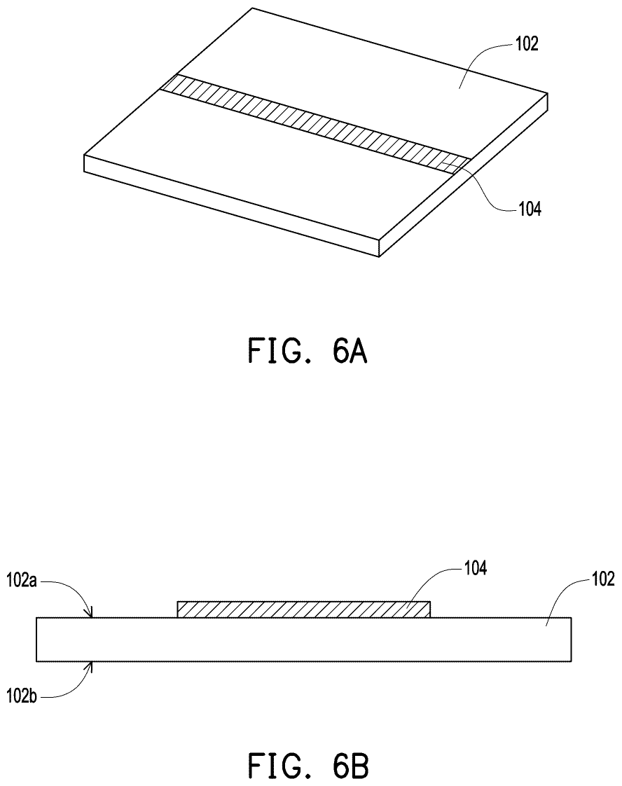

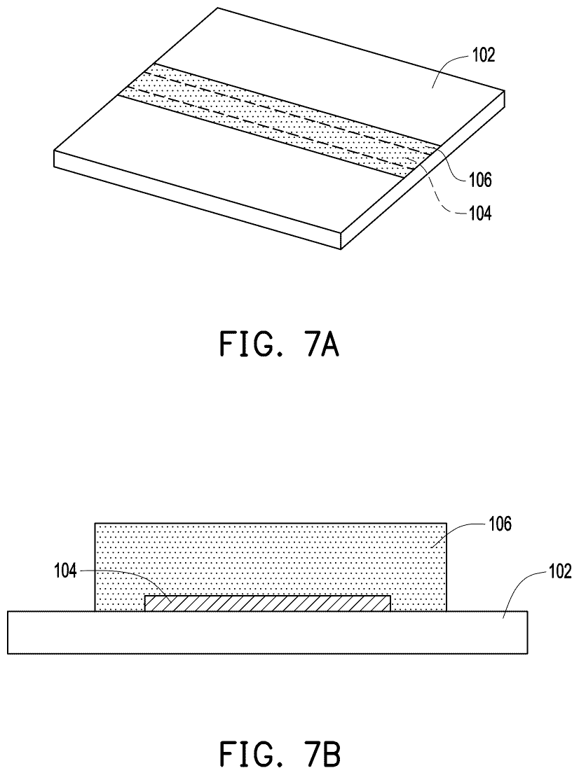

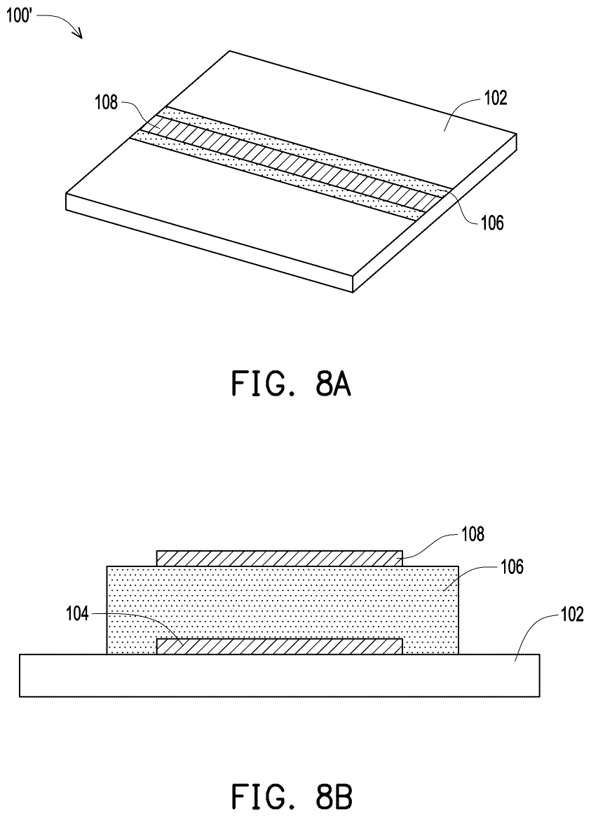

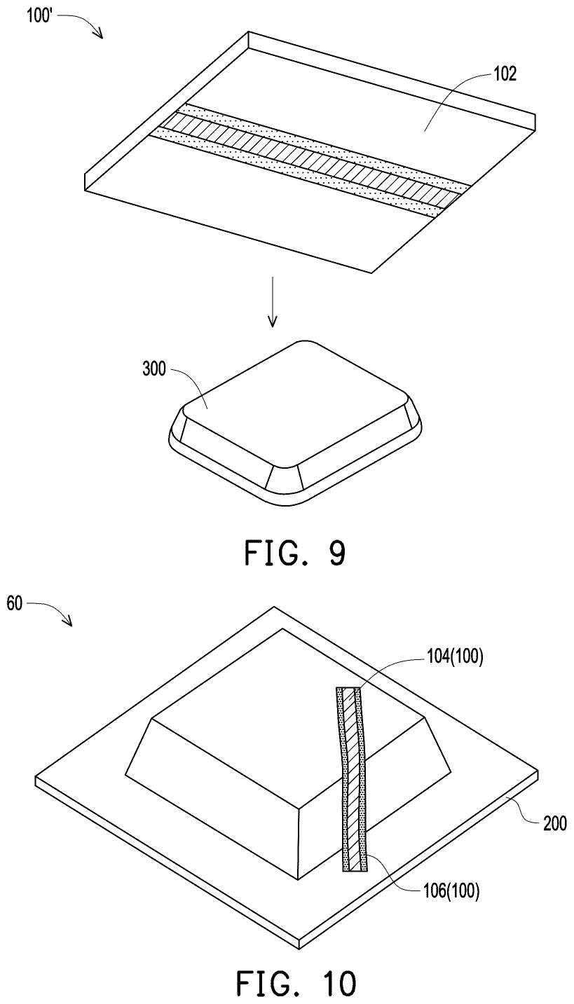

FIG. 6A and FIG. 6B, FIG. 7A and FIG. 7B, FIG. 8A and FIG. 8B, FIG. 9, and FIG. 10 are schematic views of a manufacturing process of an electronic device 60 according to an embodiment of the disclosure. FIG. 6A, FIG. 7A, FIG. 8A, FIG. 9, and FIG. 10 are schematic three-dimensional views, and FIG. 6B, FIG. 7B, and FIG. 8B may be respectively partial schematic cross-sectional views of FIG. 6A, FIG. 7A, and FIG. 8A. FIG. 6A and FIG. 6B, FIG. 7A and FIG. 7B, FIG. 8A and FIG. 8B, FIG. 9, and FIG. 10 continue to use the reference numerals and some content of the embodiment of FIG. 1A to FIG. 1C, wherein the same or similar numerals are adopted to represent the same or similar elements, and the description of the same technical content is omitted. For the description of the omitted part, reference may be made to the foregoing embodiments and will not be elaborated here. For clarity of illustration, the substrate 102 is omitted in FIG. 10, and the omitted part may be understood with reference to FIG. 1A.

Please refer to FIG. 6A and FIG. 6B, FIG. 7A and FIG. 7B, and FIG. 8A and FIG. 8B. The substrate 102 is provided. Then, staggered stacked conductive lines and dielectric patterns, such as the first conductive line 104, the first dielectric pattern 106, and the second conductive line 108, are sequentially formed on the first surface 102a of the substrate 102 according to the layout design of the surface structure 100. The layout design of the surface structure 100 may be completed according to the shape, the material, the size, etc. of the mold and the shape, the material, the size, the layout position, etc. of the surface structure (including the substrate, the conductive line, the dielectric pattern, etc.) to be formed by simulating the tensile rate of the conductive line under various cases through a software and designing the width corresponding to the dielectric pattern, the thickness ratio of the dielectric pattern to the adjacent conductive line, and/or the routing direction of the conductive line accordingly. In this way, the corresponding circuit structure may be formed on the substrate 102 according to the layout design. Specifically, through a screen printing process or other suitable printing processes, the first conductive line 104 may be formed on the substrate 102 (as shown in FIG. 6A and FIG. 6B). Then, a dielectric material layer may be formed on the substrate 102 and the first conductive line 104, and the dielectric material layer may be patterned to form the first dielectric pattern 106 overlapping with the first conductive line 104 (as shown in FIG. 7A and FIG. 7B). Afterwards, through the screen printing process or other suitable printing processes, the second conductive line 108 may be formed on the first dielectric pattern 106 (as shown in FIG. 8A and FIG. 8B). Based on the above, an initial surface structure 100′ may be obtained. The embodiment takes two conductive line layers as an example, but is not intended to limit the disclosure. In other embodiments, more layers of circuits may be formed through repeating the formation steps of the conductive lines and the dielectric patterns.

Please refer to FIG. 9. The initial surface structure 100′ is formed into the surface structure 100 having protrusions or recesses through the thermoplastic molding process. For example, a mold 300 may be used to place the initial surface structure 100′ thereon, and the initial surface structure 100′ may be extended along a surface of the mold 300 through a heating and/or pressing process to form the surface structure 100 with the morphology corresponding to the mold 300.

In some embodiments, the initial surface structure 100′ is disposed with the first surface 102a of the substrate 102 facing the mold 300, so circuit structures such as the first conductive line 104, the first dielectric pattern 106, and the second conductive line 108 are located between the substrate 102 and the mold 300 during the thermoplastic forming process. However, the disclosure is not limited thereto. In other embodiments, the initial surface structure 100′ may be disposed with the second surface 102b of the substrate 102 facing the mold 300 to perform the thermoplastic molding process, wherein the second surface 102b is a surface opposite to the first surface 102a.

Please refer to FIG. 10. The molding body 200 may be formed on the surface structure 100 through an injection molding process or other suitable processes. For example, the surface structure 100 may be disposed in a mold (not shown). Then, the molding body 200 is formed in the mold through the injection molding technique, such that the surface of the molding body 200 corresponds to and matches the surface structure 100, wherein the first surface 102a of the substrate 102 faces the molding body 200, so that the first conductive line 104, the first dielectric pattern 106, and the second conductive line 108 are located between the substrate 102 and the molding body 200.

Based on the above, the manufacturing of the electronic device 60 may be roughly completed.

The following experiments are listed to verify the efficacy of the disclosure, but the disclosure is not limited to the following content. The used materials, shapes, sizes, and layout designs, the processing details, the processing procedures, etc. may be appropriately changed without exceeding the scope of the disclosure. Therefore, the disclosure should not be interpreted restrictively by the examples described below.

The following examples and comparative examples provide various configurations of a surface structure and simulate the maximum stress subjected to a conductive line in the surface structure and the condition of the conductive line of the surface structure obtained through thermoplastic molding under the same process conditions through an engineering simulation software.

### Example 1

The surface structure 100 included the substrate 102, the first conductive line 104, the first dielectric pattern 106, and the second conductive line 108 that were sequentially stacked. The orthographic projection shapes of the first conductive line 104, the first dielectric pattern 106, and the second conductive line 108 on the projection surface P were sinusoidal waveforms, similar to the configuration of FIG. 3A and FIG. 3B. The material of the substrate 102 was polycarbonate with a thickness of 0.5 mm. The materials of the first conductive line 104 and the second conductive line 108 were silver with thicknesses of 10 μm. The material of the first dielectric pattern 106 was silicone resin with a thickness of 10 μm. The first conductive line 104 and the second conductive line 108 had uniform widths, such as 0.5 mm, that is, the widths of the first conductive line 104 and the second conductive line 108 at the peaks or the troughs and the widths at the equilibrium positions were all 0.5 mm. The width of the first dielectric pattern 106 corresponding to the peak or the trough of the conductive line was 4 mm, and the width of the first dielectric pattern 106 corresponding to the equilibrium position of the conductive line was 1 mm.

### Comparative Example 1

The surface structure 100 of Comparative Example 1 was similar to the surface structure 100 of Example 1, except that the first dielectric pattern 106 had a uniform width, such as 1 mm, that is, the width of the first dielectric pattern 106 at the peak or the trough of the conductive line and the width at the equilibrium position were both 1 mm.

Under the same simulation conditions, when the tensile rate was greater than or equal to 100%, the maximum stress of the first conductive line 104 or the second conductive line 108 observed in Example 1 was approximately 0.94 MPa, and there was no delamination, line breakage, and short circuit of upper and lower conductive lines during actual manufacturing and molding; and the maximum stress of the first conductive line 104 or the second conductive line 108 observed in Comparative Example 1 was approximately 1.2 MPa, and delamination occurred during actual manufacturing and molding. It can be seen that through the first dielectric pattern 106 of Example 1 having different widths according to the tensile rate or the deformation stress subjected to the first conductive line and the second conductive line at different positions, the stress subjected to the first conductive line 104 or the second conductive line 108 can be effectively lowered, thereby reducing the occurrence of delamination, line breakage, or short circuit of upper and lower conductive lines.

### Example 2

The surface structure 100 included the substrate 102, the first conductive line 104, the first dielectric pattern 106, and the second conductive line 108 that were sequentially stacked. The orthographic projection shapes of the first conductive line 104, the first dielectric pattern 106, and the second conductive line 108 on the projection surface P were linear shapes, similar to the configuration of FIG. 2A. The material of the substrate 102 was polycarbonate with a thickness of 0.5 mm. The materials of the first conductive line 104 and the second conductive line 108 were silver with thicknesses of 10 μm. The material of the first dielectric pattern 106 was silicone resin with a thickness of 10 μm. The first conductive line 104 and the second conductive line 108 had uniform widths, such as 0.5 mm. The first dielectric pattern 106 had a uniform width, such as 2 mm. From a top view angle, the included angles θ between the routing directions L and the tensile directions F of the first conductive line 104 and the second conductive line 108 were 45 degrees.

### Comparative Example 2

The surface structure 100 of Comparative Example 2 was similar to the surface structure 100 of Example 2, but from a top view angle, the included angles θ between the routing directions L and the tensile directions F of the first conductive line 104 and the second conductive line 108 were 0 degrees, that is, the routing directions L were the same as the tensile directions F.

Under the same simulation conditions, when the tensile rate was greater than or equal to 100%, the maximum stress of the first conductive line 104 or the second conductive line 108 observed in Example 2 was approximately 0.95 MPa, and there was no delamination, line breakage, and short circuit of upper and lower conductive lines during actual manufacturing and molding; and the maximum stress of the first conductive line 104 or the second conductive line 108 observed in Comparative Example 2 was approximately 1.85 MPa, and line breakage occurred during actual manufacturing and molding. It can be seen that through the routing directions L and the tensile directions F of the first conductive line 104 and the second conductive line 108 being different (that is, corresponding to Example 2), the stress subjected to the first conductive line 104 or the second conductive line 108 can be effectively lowered, thereby reducing the occurrence of delamination, line breakage, or short circuit of upper and lower conductive lines.

### Example 3

The surface structure 100 included the substrate 102, the first conductive line 104, the first dielectric pattern 106, and the second conductive line 108 that were sequentially stacked. The orthographic projection shapes of the first conductive line 104, the first dielectric pattern 106, and the second conductive line 108 on the projection surface P were linear shapes, similar to the configuration of FIG. 1A. The material of the substrate 102 was polycarbonate with a thickness of 0.5 mm. The materials of the first conductive line 104 and the second conductive line 108 were silver with thicknesses of 20 μm. The material of the first dielectric pattern 106 was silicone resin with a thickness of 40 μm. Therefore, the ratio of the thickness of the first dielectric pattern 106 to the thickness of the first conductive line 104 and the ratio of the thickness of the first dielectric pattern 106 to the thickness of the second conductive line 108 were 2. The first conductive line 104 and the second conductive line 108 had uniform widths, such as 0.5 mm. The first dielectric pattern 106 had a uniform width, such as 2 mm.

### Comparative Example 3

The surface structure 100 of Comparative Example 3 was similar to the surface structure 100 of Example 3, except that the thicknesses of the first conductive line 104 and the second conductive line 108 were 10 μm, and the thickness of the first dielectric pattern 106 was 110 μm, that is, the ratio of the thickness of the first dielectric pattern 106 to the thickness of the first conductive line 104 and the ratio of the thickness of the first dielectric pattern 106 to the thickness of the second conductive line 108 were 11.

Under the same conditions, when the tensile rate was greater than or equal to 100%, the maximum stress of the first conductive line 104 or the second conductive line 108 observed in Example 3 was approximately 0.98 MPa, and there was no delamination, line breakage, and short circuit of upper and lower conductive lines during actual manufacturing and molding; and the maximum stress of the first conductive line 104 or the second conductive line 108 observed in Comparative Example 3 was approximately 1.5 MPa, and delamination occurred during actual manufacturing and molding. It can be seen that through the ratio of the thickness of the first dielectric pattern 106 to the thickness of the first conductive line 104 and/or the ratio of the thickness of the first dielectric pattern 106 to the thickness of the second conductive line 108 being within the range of 0.5 to 10, the stress subjected to the first conductive line 104 or the second conductive line 108 can be effectively lowered, thereby reducing the occurrence of delamination, line breakage, or short circuit of upper and lower conductive lines.

It can be inferred from Examples 1 to 3 above that the stress subjected to the conductive line in the surface structure may be reduced through adjusting the width of the corresponding dielectric pattern, the thickness ratio of the corresponding dielectric pattern to the conductive line, any one of the routing direction and the tensile direction of the conductive line, or a combination thereof.

In summary, the electronic structure of the disclosure includes the surface structure. The surface structure includes the conductive line and the dielectric pattern corresponding to the conductive line. Through the dielectric pattern having different widths according to the tensile rate subjected to the corresponding conductive line, through controlling the thickness ratio of the dielectric pattern to the corresponding conductive line, or through the routing direction of the conductive line being different from the tensile direction subjected thereto, the deformation stress subjected to the conductive line can be alleviated to reduce the risk of delamination or breakage of the conductive line, thereby improving the reliability of the electronic device.

It will be apparent to those skilled in the art that various modifications and variations may be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An electronic device, comprising:
a surface structure, having a curved surface, wherein the surface structure comprises:
a substrate;
a first conductive line, disposed above the substrate; and
a first dielectric pattern, disposed above and overlapping with the first conductive line,
wherein the surface structure has a first region and a second region, the first dielectric pattern in the first region has a first average width, the first dielectric pattern in the second region has a second average width, and the first average width is different from the second average width.

2. The electronic device according to claim 1, wherein the surface structure is stretched to form the curved surface, and a tensile rate subjected to the first conductive line in the second region is greater than a tensile rate subjected to the first conductive line in the first region.

3. The electronic device according to claim 2, wherein the second average width is greater than the first average width.

4. The electronic device according to claim 3, wherein a ratio of the second average width to the first average width is between 1.2 and 8.

5. The electronic device according to claim 1, wherein the first conductive line has a third average width in the first region, the first conductive line has a fourth average width in the second region, and a ratio of the first average width to the third average width is different from a ratio of the second average width to the fourth average width.

6. The electronic device according to claim 1, wherein the first dielectric pattern has a first average thickness, the first conductive line has a second average thickness, and a ratio of the first average thickness to the second average thickness is between 0.5 and 10.

7. The electronic device according to claim 1, further comprising:
a second conductive line, disposed above the first dielectric pattern, wherein orthographic projection shapes of the first conductive line and the second conductive line on a projection surface respectively comprise a linear shape, a serpentine shape, an S shape, a horseshoe shape, a wavy shape, or a square waveform.

8. The electronic device according to claim 1, wherein the surface structure is stretched to form the curved surface, an orthographic projection of the first conductive line on a projection surface extends in a first direction, an orthographic projection of a tensile direction subjected to a point on the first conductive line on the projection surface extends in a second direction, and the second direction is different from the first direction.

9. The electronic device according to claim 1, wherein a material of the substrate is selected from a group composed of polyethylene terephthalate, polyethylene terephthalate-1,4-cyclohexane dimethanol, polycarbonate, polyimide, polymethyl methacrylate, polyphenylene ether styrene, polydimethylsiloxane, ABS resin, and acrylic resin.

10. The electronic device according to claim 1, wherein a material of the first dielectric pattern is selected from a group composed of acrylic resin, epoxy resin, phenolic resin, polyester resin, polyurethane resin, silicone resin, polyimide, and a solution gas barrier material.

11. An electronic device, comprising:
a substrate, having a curved surface;
a first conductive line, disposed above the substrate, wherein the first conductive line has a first thickness;
a second conductive line, disposed above the first conductive line, wherein the second conductive line has a second thickness; and
a first dielectric pattern, disposed between the first conductive line and the second conductive line, wherein the first dielectric pattern has a third thickness, wherein a ratio of the third thickness to the first thickness and a ratio of the third thickness to the second thickness are respectively between 0.5 and 10.

12. The electronic device according to claim 11, wherein a ratio of the second thickness to the first thickness is between 1 and 5.

13. The electronic device according to claim 11, further comprising:
a third conductive line, disposed above the second conductive line; and
a second dielectric pattern, disposed between the second conductive line and the third conductive line,
wherein the second conductive line intersects the third conductive line, and a part of the second dielectric pattern is disposed between the substrate and the third conductive line and directly contacts the substrate.

14. The electronic device according to claim 11, wherein the first dielectric pattern completely overlaps with and directly contacts the first conductive line and the second conductive line.

15. The electronic device according to claim 11, wherein an orthographic projection shape of the first dielectric pattern corresponds to an orthographic projection shape of the first conductive line and an orthographic projection shape of the second conductive line.

16. An electronic device, comprising:
a surface structure, comprising:
a flexible substrate; and
a first conductive line, disposed on the flexible substrate, wherein the surface structure is stretched to form a curved surface,
wherein a routing direction of the first conductive line on a projection surface is different from a component force direction of a tensile force parallel to the projection surface subjected to any point on the first conductive line.

17. The electronic device according to claim 16, wherein there is an included angle between the routing direction and the tensile direction, and the included angle is between 15 degrees and 75 degrees or between 105 degrees and 165 degrees.

18. The electronic device according to claim 16, wherein the surface structure further comprises:
a first dielectric pattern, disposed on the first conductive line, wherein a shape of the first dielectric pattern corresponds to a shape of the first conductive line.

19. The electronic device according to claim 18, wherein an included angle between an extension direction of the first dielectric pattern on the projection surface and the component force direction is between 15 degrees and 75 degrees or between 105 degrees and 165 degrees.

20. The electronic device according to claim 16, wherein a tensile rate subjected to the first conductive line is greater than or equal to 5%.
